(19) United States
(12) Patent Application Publication
(10) Pub. No.: US 2025/0006622 A1
(43) Pub. Date: Jan. 2, 2025

(54) SEMICONDUCTOR MODULE AND MANUFACTURING METHOD THEREOF

(71) Applicant: FUJI ELECTRIC CO., LTD., Kawasaki-shi (JP)

(72) Inventor: Tatsuo NISHIZAWA, Matsumoto-city (JP)

(73) Assignee: FUJI ELECTRIC CO., LTD., Kawasaki-shi (JP)

(21) Appl. No.: 18/644,494

(22) Filed: Apr. 24, 2024

(30) Foreign Application Priority Data
Jun. 28, 2023 (JP) 2023-106092

(51) Int. Cl. H01L 23/498; H01L 21/56; H01L 23/00; H01L 23/31; H01L 23/373

(52) U.S. Cl. CPC H01L 23/49861; H01L 21/56; H01L 23/3121; H01L 23/3735; H01L 24/32; H01L 24/40; H01L 24/73; H01L 24/83; H01L 24/84; H01L 24/92; H01L 2224/32225; H01L 2224/40175; H01L 2224/73263; H01L 2224/8384; H01L 2224/84203; H01L 2224/92246

(57) ABSTRACT

A semiconductor module manufacturing method includes: preparing an insulating wiring substrate 10 including a substrate and a first conductor provided on the substrate, a semiconductor chip 20 having a first surface and a second surface, and a printed wiring board 50 including an insulating substrate and a lead frame 52 provided on the insulating substrate, the lead frame including a first portion 52a provided in a first via-hole penetrating through the insulating substrate; disposing the first surface on the first conductor via a first sintering material; disposing an insulating sheet on the insulating wiring substrate to surround the semiconductor chip; disposing the printed wiring board such that the insulating substrate faces the insulating sheet and the first portion makes contact with the second surface via a second sintering material; and heating the insulating wiring substrate, the semiconductor chip, the insulating sheet, and the printed wiring board while they are pressurized.

### CROSS-REFERENCE TO RELATED APPLICATION

This application claims benefit of priority under 35 USC 119 based on Japanese Patent Application No. 2023-106092 filed on Jun. 28, 2023, the entire contents of which are incorporated by reference herein.

### BACKGROUND OF THE INVENTION

### 1. Field of the Invention

This disclosure relates to a semiconductor module including a semiconductor chip, and a manufacturing method thereof.

### 2. Description of the Related Art

A power semiconductor device is a semiconductor device to which heavy-current can be applied at a high voltage, which can deal with direct-current voltage and alternating-current voltage, and which can convert the direct-current voltage to the alternating-current voltage and vice versa. The power semiconductor device can change the voltage and the frequency of the alternating-current voltage and is widely used for a rotation control of a motor. A general power semiconductor device includes a semiconductor chip including a semiconductor element such as an insulated gate bipolar transistor (IGBT) or an MOS field effect transistor (MOSFET), a printed circuit board (PCB), an isolation circuit board, a heat dissipation base, and so on. For joining between the semiconductor chip, the isolation circuit board, and the heat dissipation base, a solder material, a sintering material, wire bonding, or the like is used.

WO 2016/152258 discloses “a semiconductor device including a heat dissipation substrate, an insulating substrate disposed on the heat dissipation substrate and including a wiring layer, a plurality of semiconductor elements disposed on the insulating substrate, a conductive block electrically connected to surface electrodes of the semiconductor elements, and a terminal electrode, the conductive block including a projection, and the projection being joined to the insulating substrate.”

JP 2021-027288 A discloses that “a semiconductor device includes a semiconductor chip, an isolation circuit board disposed to face a lower surface of the semiconductor chip, and a first sintering metal layer disposed on an upper surface of the isolation circuit board and including a joined portion in contact with the semiconductor chip and an outer edge surrounding the joined portion, and in the first sintering metal layer, a void volume indicative of the volume density of voids included in the first sintering metal layer is uniform between the joined portion and the outer margin.”

JP 2018-006492 A discloses “a semiconductor device including a substrate, a semiconductor chip provided on the substrate and including a front-surface electrode and a back-surface electrode on the opposite side from the front-surface electrode, a lead frame disposed to face the front-surface electrode of the semiconductor chip, a first joined portion formed between the substrate and the back-surface electrode of the semiconductor chip, and a second joined portion formed between the front-surface electrode of the semiconductor chip and the lead frame, the lead frame including electrode portions connected to the front-surface electrode via the second joined portion, a bridge member connecting the electrode portions to each other, and a resin layer formed on upper surfaces of the electrode portions, the resin layer being formed on respective parts of a lower surface of the bridge member and lower surfaces of the electrode portions, the respective parts being not joined to the front-surface electrode.”

In recent years, as for the power semiconductor device, high integration of a circuit has expanded to meet a demand of a reduction in size and weight and a high function. Furthermore, application to a semiconductor device using a semiconductor element such as silicon carbide (SiC) that can work at high temperature has been developed, so that a high reliability of the semiconductor device under a high-temperature operating environment has been demanded. On this account, as a bonding material corresponding to high-temperature operation, a sintering metal layer using sintering action of metal particles of silver (Ag), copper (Cu), or the like has been considered.

In order to sinter a sintering material, it is necessary to apply uniform pressure and heat to a part to be sintered. When the pressure is ununiform, air bubbles might be generated in a resultant sintered body, which might cause a semiconductor chip to have an unstable joining quality.

### SUMMARY OF THE INVENTION

This disclosure is accomplished in view of the above problems, and an object of this disclosure is to provide a semiconductor module corresponding to high-temperature operation and a manufacturing method thereof.

In order to achieve the above object, a semiconductor module manufacturing method according to one aspect of this disclosure includes: preparing an insulating wiring substrate including a substrate and a first conductor provided on an upper surface of the substrate, a semiconductor chip having a first surface and a second surface, and a printed wiring board including an insulating substrate and a lead frame provided on the insulating substrate, the lead frame including a first portion provided in a first via-hole penetrating through the insulating substrate; disposing the first surface of the semiconductor chip on the first conductor via a first sintering material; disposing an insulating sheet on the insulating wiring substrate to surround the semiconductor chip in a plan view; disposing the printed wiring board such that the insulating substrate faces the insulating sheet and the first portion makes contact with the second surface via a second sintering material; and heating the insulating wiring substrate, the semiconductor chip, the insulating sheet, and the printed wiring board while they are pressurized.

In order to achieve the above object, a semiconductor module according to another aspect of this disclosure includes: an insulating wiring substrate including a substrate and a first conductor provided on an upper surface of the substrate; a semiconductor chip having a first surface and a second surface, the first surface being joined to the first conductor via a first sintered body; an insulating sheet provided on the insulating wiring substrate to surround the semiconductor chip in a plan view; and a printed wiring board including an insulating substrate and a lead frame provided on the insulating substrate, the lead frame including a first portion provided in a first via-hole penetrating through the insulating substrate and joined to the second surface via a second sintered body, the insulating substrate facing the insulating sheet.

### BRIEF DESCRIPTION OF THE DRAWINGS

FIG. 1 is a longitudinal-section schematic view illustrating an example of a schematic configuration of a semiconductor module according to a first embodiment of this disclosure;

FIG. 2 is a longitudinal-section schematic view illustrating an example of the schematic configuration of the semiconductor module according to the first embodiment of this disclosure;

FIG. 3 is a procedure drawing schematically illustrating a manufacturing method of the semiconductor module according to the first embodiment of this disclosure;

FIG. 4 is a procedure sectional view following FIG. 3;

FIG. 5 is a procedure sectional view following FIG. 4;

FIG. 6 is a procedure sectional view following FIG. 5;

FIG. 7 is a procedure sectional view following FIG. 6;

FIG. 8 is a procedure sectional view following FIG. 7;

FIG. 9 is a procedure sectional view following FIG. 8;

FIG. 10 is a longitudinal-section schematic view illustrating a lead frame in FIG. 1 in an enlarged manner;

FIG. 11 is a table illustrating characteristics of various bonding materials;

FIG. 12 is a longitudinal-section schematic view illustrating an example of a schematic configuration of a main part of a semiconductor module according to a second embodiment of this disclosure;

FIG. 13 is a procedure drawing schematically illustrating a manufacturing method of the semiconductor module according to the second embodiment of this disclosure;

FIG. 14 is a procedure drawing schematically illustrating the manufacturing method of the semiconductor module according to the second embodiment of this disclosure;

FIG. 15 is a procedure sectional view following FIG. 14;

FIG. 16 is a longitudinal-section schematic view illustrating an example of a schematic configuration of a main part of a semiconductor module according to a third embodiment of this disclosure;

FIG. 17 is a procedure drawing schematically illustrating a manufacturing method of the semiconductor module according to the third embodiment of this disclosure;

FIG. 18 is a procedure sectional view following FIG. 17; and

FIG. 19 is a longitudinal-section schematic view illustrating another exemplary configuration of the lead frame.

### DETAILED DESCRIPTION

With reference to the drawings, the following describes embodiments of this disclosure. In the description of the drawings, identical or similar parts have identical or similar reference signs and redundant descriptions are omitted. Note that, the drawings are schematic, and a relationship between thickness and flat dimension, a ratio between layer thicknesses, and the like are different from actual ones. Further, the drawings may include parts having different dimensional relationships or ratios. Further, the embodiments described below describe examples of devices or methods to embody the technical idea of this disclosure, and the technical idea of this disclosure does not limit a material, a shape, a structure, an arrangement, and the like of a constituent component to those described below. Further, various changes can be added to the technical idea of this disclosure within a technical scope defined by claims described in Claims.

In the present specification, a source region of a metal-oxide-semiconductor field-effect transistor (MOSFET) is “one main region (a first main region)” selectable as an emitter region of an insulated gate bipolar transistor (IGBT). Further, in a thyristor such as an MOS-controlled static induction thyristor (SI thyristor), the “one main region” is selectable as a cathode region. A drain region of the MOSFET is “the other main region (a second main region)” of a semiconductor device that is selectable as a collector region in the IGBT or an anode region in the thyristor. When the “main region” is just referred to in the present specification, the “main region” indicates proper one of the first main region and the second region based on a common general technical knowledge of those skilled in the art.

Further, the definitions of directions such as “up” and “down” in the following description are merely definitions for convenience of the description and do not restrict the technical idea of this disclosure. For example, when a target is rotated by 90 degrees and observed, its top and bottom are replaced with right and left, and when the target is rotated by 180 degrees and observed, the top and bottom are upside down. Further, an “upper surface” may be read as a “front surface,” and a “lower surface” may be read as a “back surface.”

### First Embodiment

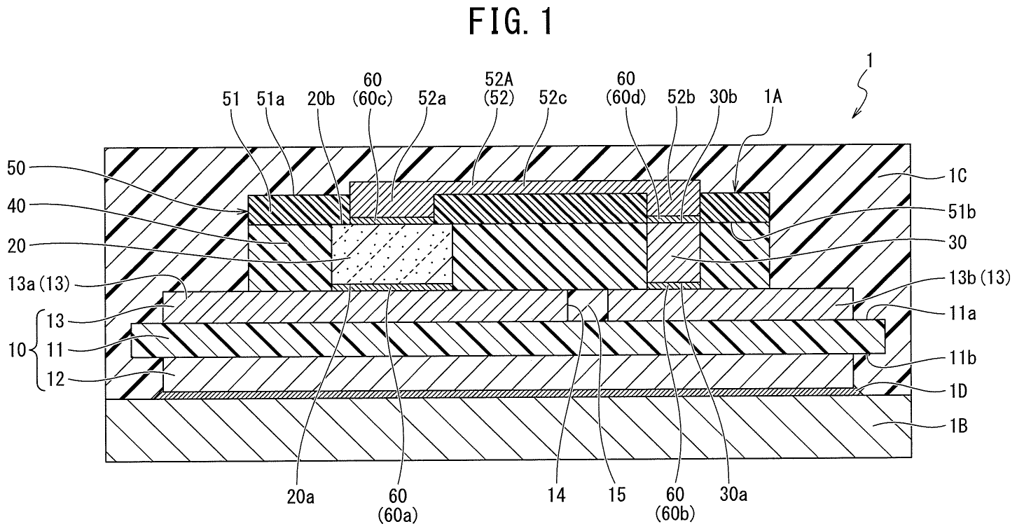

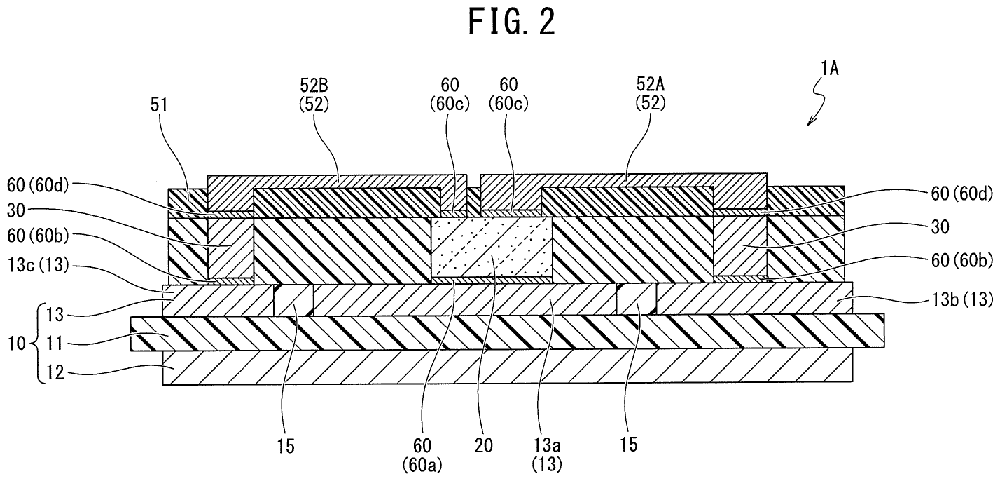

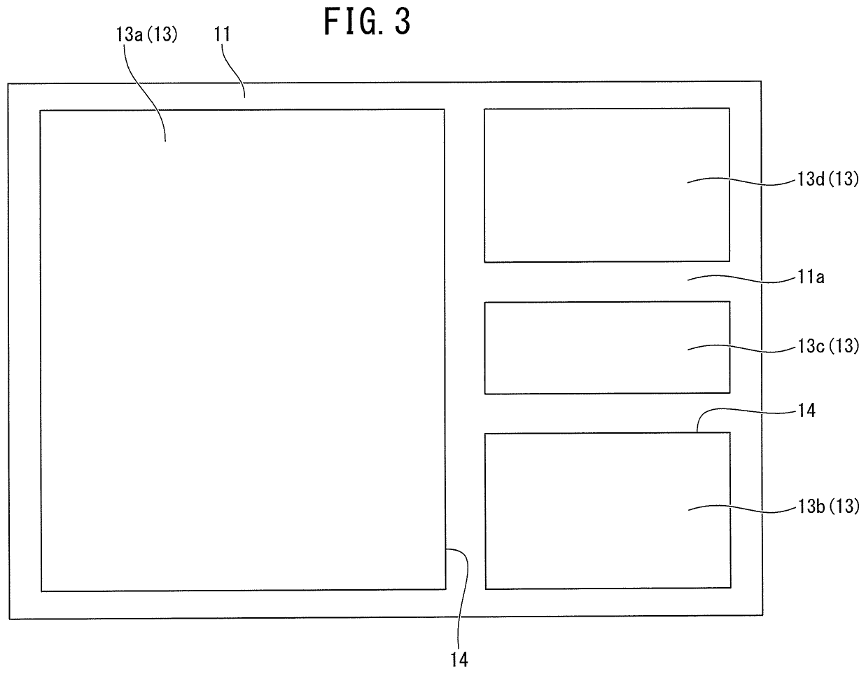

The configuration of a semiconductor module according to a first embodiment of this disclosure will be described with reference to FIGS. 1, 2. Note that the procedure drawings of a manufacturing method illustrated in FIGS. 3 to 9 will be referred to appropriately to describe the positional relationship between components.

### <<Configuration of Semiconductor Module>>

As illustrated in FIG. 1, a semiconductor module 1 includes, for example, a main part 1A, a copper base 1B, and a sealing resin 1C. The main part 1A is a power semiconductor device and is joined to an upper surface of the copper base 1B via a bonding layer 1D. The bonding layer 1D is made of a bonding material having a heat transfer property, e.g., solder, a heat dissipation compound, and the like. Since the main part 1A is joined to the upper surface of the copper base 1B, heat generated in the main part 1A can escape to the copper base 1B. Note that the main part 1A may be joined to a cooling fin instead of the copper base 1B. The sealing resin 1C is provided on the upper surface side of the copper base 1B and covers the upper surface of the copper base 1B and the main part 1A. The sealing resin 1C is made of, for example, a material such as epoxy resin. Since the sealing resin 1C seals the main part 1A, it is possible to improve the reliability of the semiconductor module 1.

### <Main Part>

The main part 1A includes an insulating wiring substrate 10, a semiconductor chip 20, a conductor block 30, an insulating sheet 40, and a printed wiring board 50.

### (Insulating Wiring Substrate)

The insulating wiring substrate 10 is, for example, a DCB (Direct Copper Bonding) substrate or an AMB (Active Metal Brazing) substrate. As illustrated in FIG. 1, the insulating wiring substrate 10 includes a substrate 11 made of an insulating material, and a heat transfer member 12 provided on a lower surface 11b of the substrate 11. The substrate 11 (see FIG. 3) and the heat transfer member 12 have, for example, a rectangular flat-plate shape. As illustrated in FIG. 1, a lower surface (a surface opposite the substrate 11 side) of the heat transfer member 12 is joined to the upper surface of the copper base 1B via the bonding layer 1D.

As illustrated in FIGS. 1, 3, the insulating wiring substrate 10 includes a plurality of conductors 13 provided on an upper surface 11a of the substrate 11. The plurality of conductors 13 is electrically isolated from each other. As illustrated in FIG. 3, the plurality of conductors 13 is referred to as conductors 13a, 13b, 13c, 13d to distinguish them from each other. When the plurality of conductors 13a, 13b, 13c, 13d is not distinguished from each other, they are just referred to as the conductors 13. Note that the number of conductors 13 is not limited to the number illustrated in FIG. 3 as long as the number is plural. Further, FIG. 1 illustrates longitudinal sections of the conductors 13a, 13b from among the plurality of conductors 13. Since the conductor 13 has a thickness, a recessed portion 14 is constituted by lateral faces of adjacent conductors 13 and the upper surface 11a of the substrate 11, as illustrated in FIG. 1. The recessed portion 14 is filled with an insulating material 15. When the recessed portion 14 is filled with the insulating material 15, a step between an upper surface (a surface on the insulating sheet 40 side) of the conductor 13 and the upper surface 11a of the substrate 11 can be filled. The insulating material 15 is made of a material having an insulating property and is, for example, epoxy resin, or prepreg (described later). The insulating material 15 may be the same resin material as a material constituting the sealing resin 1C. The substrate 11 is made of ceramic such as alumina (Al₂O₃), aluminum nitride (AlN), or silicon nitride (SiN), for example. The heat transfer member 12 is preferably made of a material having a high heat conductivity and is, for example, made of copper. The conductor 13 is made of a conductor such as metal and is, for example, made of copper.

### (Semiconductor Chip)

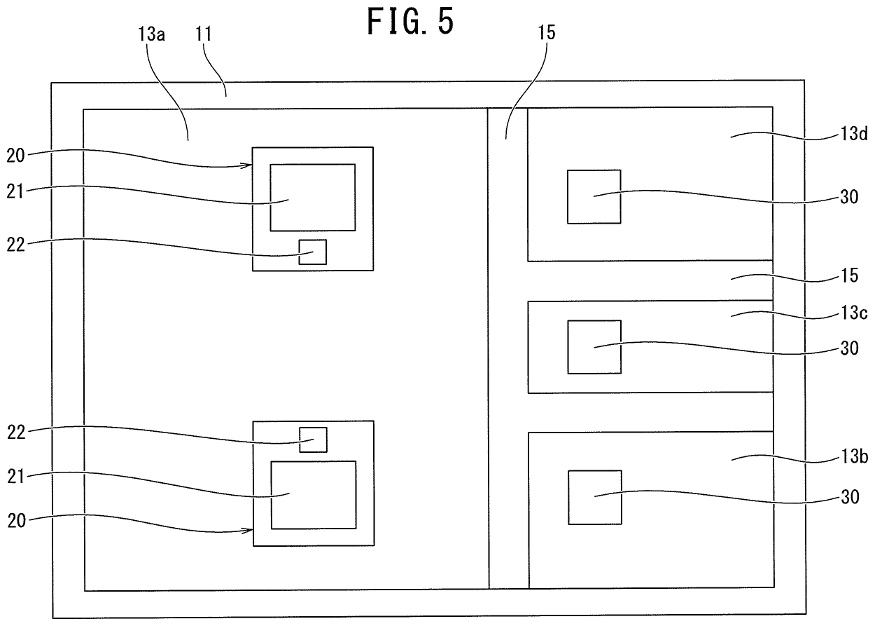

As illustrated in FIG. 5, the main part 1A includes a plurality of semiconductor chips 20. The main part 1A may include, as the semiconductor chip 20, a semiconductor chip including an on/off circuit, a semiconductor chip including a reflux circuit using a diode, a semiconductor chip including a thermistor, or the like, for example. A semiconductor layer included in each of the semiconductor chips 20 is, for example, any of silicon (Si), silicon carbide (SiC), gallium nitride (GaN), a diamond semiconductor, and the like.

The semiconductor chip including an on/off circuit includes, for example, a switching element such as an insulated gate bipolar transistor (IGBT), a power metal-oxide-semiconductor field-effect transistor (Metal-Oxide-Semiconductor Field-Effect Transistor: MOSFET), a reverse conductive IGBT (RC-IGBT), or a reverse-blocking IGBT (RB-IGBT). The semiconductor chip 20 including an on/off circuit includes, on a second surface 20b side, a terminal 21 (FIG. 5) electrically connected to a first main region of the switching element, and includes, on a first surface 20a side, a terminal (not illustrated) electrically connected to a second main region, for example. Further, the semiconductor chip 20 including an on/off circuit includes, on the second surface 20b side, a terminal 22 (FIG. 5) electrically connected to a gate electrode of the switching element. In the present embodiment, the configuration will be described with the semiconductor chip 20 including an on/off circuit being taken as an example.

As illustrated in FIG. 5, the main part 1A includes two semiconductor chips 20. As illustrated in FIG. 1, the semiconductor chip 20 has the first surface 20a and the second surface 20b, and the first surface 20a is joined to the conductor 13a via a sintered body 60. Hereby, a terminal electrically connected to the second main region of the switching element is joined to the conductor 13a. The sintered body 60 joining the semiconductor chip 20 to the conductor 13a is referred to as a sintered body 60a to distinguish it from the other sintered bodies. The sintered body 60a corresponds to a first sintered body. When the sintered body 60a is not distinguished from the other sintered bodies, the sintered body 60a is just referred to as the sintered body 60. Further, the conductor 13a as a conductor to which the semiconductor chip 20 is joined corresponds to a first conductor.

### (Conductor Block)

As illustrated in FIG. 1, the conductor block 30 has a third surface 30a and a fourth surface 30b. The third surface 30a of the conductor block 30 is joined to the conductor 13b via a sintered body 60. The conductor 13 to which the conductor block 30 is joined is a conductor electrically separated from the conductor 13 to which the semiconductor chip 20 is connected. The sintered body 60 joining the conductor block 30 to the conductor 13b is referred to as a sintered body 60b to distinguish it from the other sintered bodies. The sintered body 60b corresponds to a third sintered body. When the sintered body 60b is not distinguished from the other sintered bodies, the sintered body 60b is just referred to as the sintered body 60. Further, the conductor 13b as a conductor to which the conductor block 30 is joined corresponds to a second conductor. The conductor block 30 is made of a material having a conductivity, e.g., metal. The conductor block 30 is made of copper (Cu), for example.

As illustrated in FIG. 5, the main part 1A includes a plurality of conductor blocks 30. The conductor block 30 has the same thickness as the semiconductor chip 20, as illustrated in FIG. 1. More specifically, the conductor block 30 has the same thickness as the semiconductor chip 20 making a pair with the conductor block 30. The semiconductor chip 20 making a pair with the conductor block 30 is a semiconductor chip electrically connected to the conductor block 30 via a lead frame 52 (described later), as illustrated in FIG. 1.

### (Insulating Sheet)

The insulating sheet 40 is made of a material having a heat-resisting property and desirably has heat performance of a grade corresponding to FR-5 or more. More specifically, the insulating sheet 40 has heat performance at 150° C. or more and more preferably has heat performance at around 175° C. or more, 180° C. or more, or 200° C. or more. The insulating sheet 40 is prepreg. The insulating sheet 40 contains glass fiber and a thermosetting resin material immersed in the glass fiber, for example. The thermosetting resin material is any of polyimide, polyamideimide, and epoxy based resin. Further, the insulating sheet 40 may include a resin plate and adhesive layers provided on both surfaces of the resin plate, for example. The resin plate is any of polyimide, polyamideimide, liquid crystalline polymer, polyphenylene sulfide, and polyether ketone, and the adhesive layer is epoxy resin.

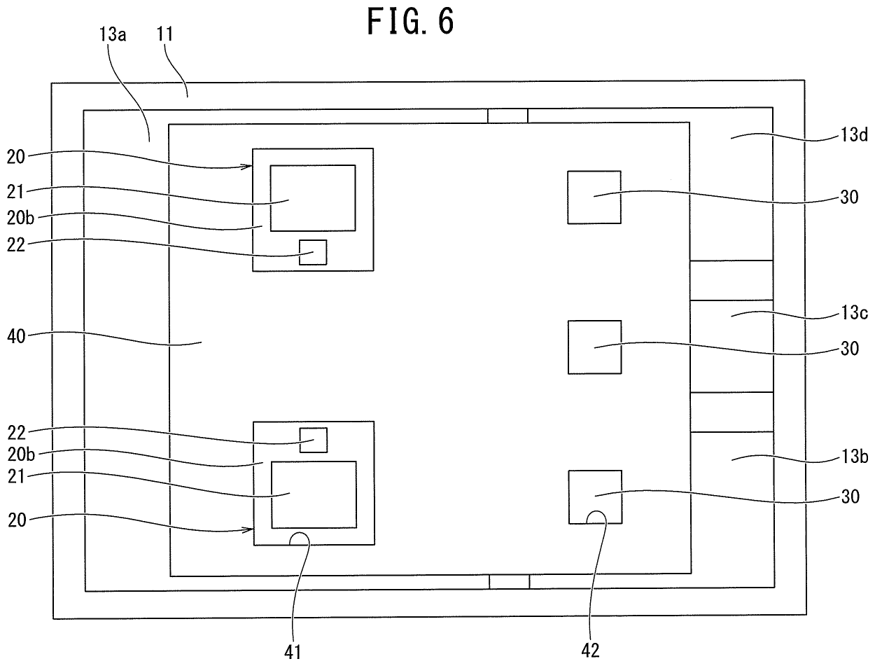

As illustrated in FIG. 1, a lower surface (one surface) of the insulating sheet 40 makes contact with the insulating wiring substrate 10. The insulating sheet 40 is disposed on the insulating wiring substrate 10 such that the insulating sheet 40 surrounds the semiconductor chip 20 and the conductor block 30. More specifically, as illustrated in FIG. 6, the insulating sheet 40 is provided over the insulating material 15, the conductor 13a, and the conductors 13b, 13c, 13d. The insulating sheet 40 has a first opening 41 for each semiconductor chip 20 and has a second opening 42 for each conductor block 30. As illustrated in FIGS. 1, 6, the semiconductor chip 20 is put in the first opening 41, and the conductor block 30 is put in the second opening 42. Note that, in order to restrain electric discharge, it is preferable that no gap be formed between the first opening 41 and the semiconductor chip 20 and between the second opening 42 and the conductor block 30, or even if gaps are formed, it is preferable that the gaps be slight.

### (Printed Wiring Board)

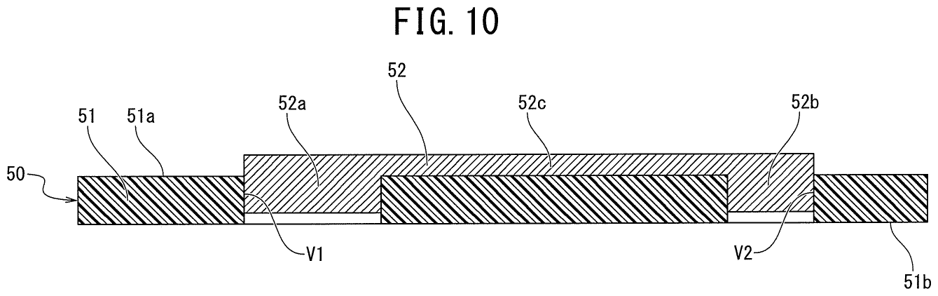

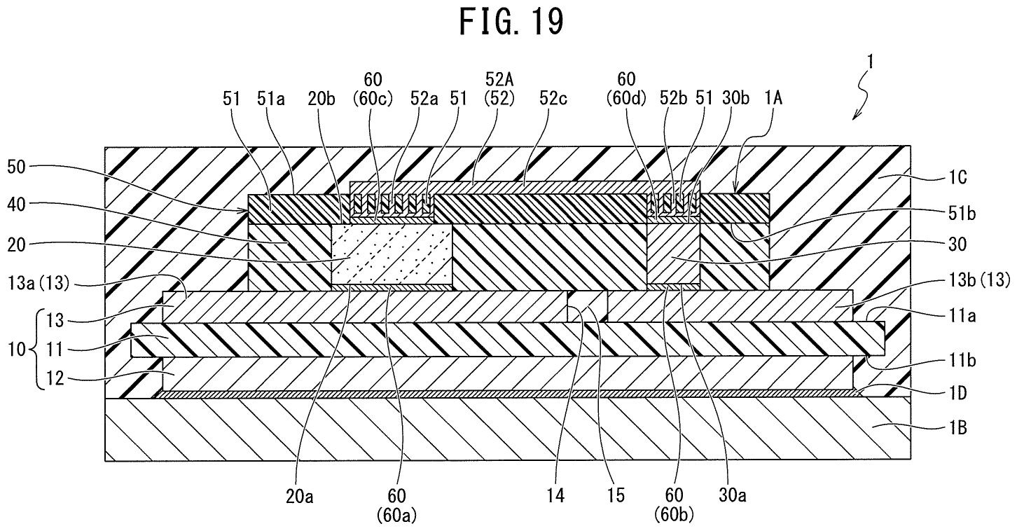

As illustrated in FIG. 1, the printed wiring board 50 is an inlaid substrate including a flat-shaped insulating substrate 51 and the lead frame 52 provided on the insulating substrate 51. The lead frame 52 is made of a conductor such as metal and can be made by use of copper, for example. The insulating substrate 51 has an upper surface 51a (a surface opposite to the insulating sheet 40 side) and a lower surface 51b (a surface on the insulating sheet 40 side). The printed wiring board 50, more specifically, the insulating substrate 51 faces the insulating sheet 40, and the lower surface 51b makes contact with an upper surface (the other surface) of the insulating sheet 40. As illustrated in FIG. 10, the insulating substrate 51 has a first via-hole V1 and a second via-hole V2 penetrating through the insulating substrate 51 in its thickness direction. The second via-hole V2 penetrates through the insulating substrate 51 at a position different from the first via-hole V1 in a plan view. The lead frame 52 includes a first portion 52a and a second portion 52b extending along the thickness direction of the insulating substrate 51, and a connecting portion 52c extending along a direction perpendicular to the thickness direction of the insulating substrate 51 and connecting the first portion 52a to the second portion 52b. The first portion 52a and the second portion 52b have the same length along their extending direction. Further, respective dimensions of the first portion 52a and the second portion 52b in a plan view are about 1.2 mm or more but 8.0 mm or less, for example, but they are not limited to this. Further, the first portion 52a and the second portion 52b may have a configuration used for a normal printed wiring board as illustrated in FIG. 19. More specifically, each of the first portion 52a and the second portion 52b may have a plurality of portions extending in the thickness direction of the insulating substrate 51.

As illustrated in FIGS. 1, 10, the connecting portion 52c is provided on the upper surface 51a side. The first portion 52a is provided in the first via-hole V1, and its end surface on the lower surface 51b side is joined to the second surface 20b of the semiconductor chip 20 via a sintered body 60. More specifically, the end surface of the first portion 52a on the lower surface 51b side is joined to the terminal 21 (FIG. 6) of the semiconductor chip 20. The sintered body 60 joining the first portion 52a to the semiconductor chip 20 is referred to as a sintered body 60c to distinguish it from the other sintered bodies. The sintered body 60c corresponds to a second sintered body. When the sintered body 60c is not distinguished from the other sintered bodies, the sintered body 60c is just referred to as the sintered body 60. The second portion 52b is provided in the second via-hole V2, and its end surface on the lower surface 51b side is joined to the fourth surface 30b of the conductor block 30 via a sintered body 60. The sintered body 60 joining the second portion 52b to the conductor block 30 is referred to as a sintered body 60d to distinguish it from the other sintered bodies. The sintered body 60d corresponds to a fourth sintered body. When the sintered body 60d is not distinguished from the other sintered bodies, the sintered body 60d is just referred to as the sintered body 60. Thus, one lead frame 52 electrically connects the semiconductor chip 20 and the conductor block 30 making a pair with each other.

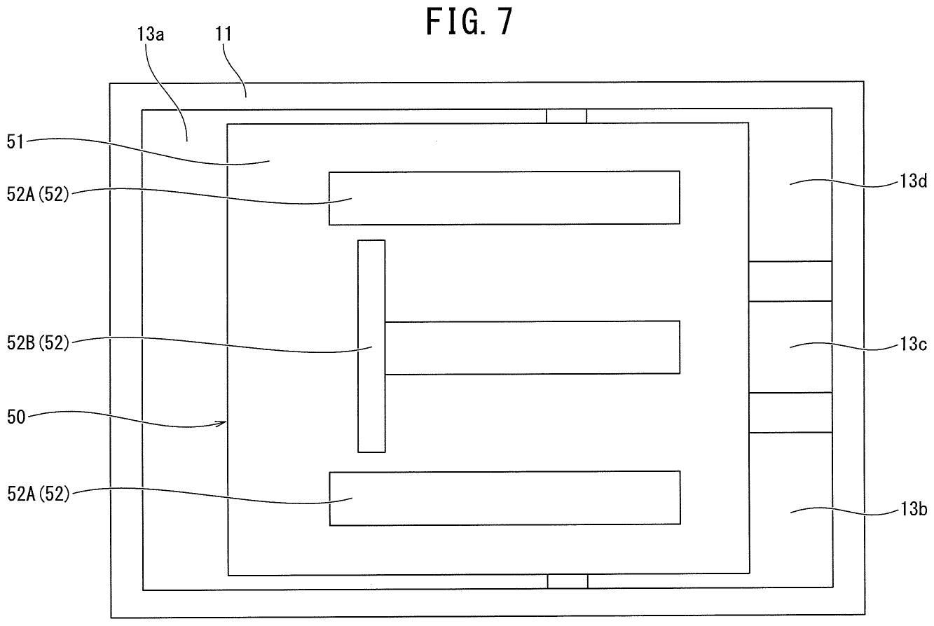

As illustrated in FIG. 7, the printed wiring board 50 includes a plurality of lead frames 52. The number of lead frames 52 to be provided is determined based on the number of semiconductor chips 20, the number of terminals provided in the semiconductor chip 20, and the like. Among the lead frames 52 provided in the printed wiring board 50, a lead frame connecting the terminal 21 (FIG. 6) of the semiconductor chip 20 to the conductor block 30 is referred to as a lead frame 52A to distinguish it from the other lead frames. FIG. 1 illustrates a longitudinal sectional configuration of the lead frame 52A. When the lead frame 52A is not distinguished from the other lead frames, the lead frame 52A is just referred to as the lead frame 52. Further, among the lead frames 52, a lead frame connecting the terminal 22 (FIG. 6) of the semiconductor chip 20 to the conductor block 30 is referred to as a lead frame 52B to distinguish it from the other lead frames. When the lead frame 52B is not distinguished from the other lead frames, the lead frame 52B is just referred to as the lead frame 52. Since the lead frame 52B is not illustrated in FIG. 1, the lead frame 52B will be described in more detail with reference to FIG. 2. Note that the main part 1A of the semiconductor module 1 illustrated in FIG. 2 has a constitution different from the main part 1A of the semiconductor module 1 illustrated in FIG. 1. The lead frame 52B has a configuration similar to that of the lead frame 52A and electrically connects the terminal 22 (FIG. 6) of the semiconductor chip 20 to the conductor block 30 joined to the conductor 13c via the sintered body 60b. Note that the semiconductor chip 20 may include a terminal (for example, a sense electrode) other than the terminals 21, 22, and even in that case, the terminal is electrically connected to the conductor block 30 via the sintered body 60 using the lead frame 52.

### <<Manufacturing Method of Semiconductor Module>>

A manufacturing method of the semiconductor module 1 will be described with reference to FIGS. 3 to 10 as follows. First, the insulating wiring substrate 10, the semiconductor chip 20, the conductor block 30, the insulating sheet 40, the printed wiring board 50, and a sintering material 61, illustrated in FIGS. 3 to 10, are prepared. As the conductor block 30, a conductor block having the same thickness as the semiconductor chip 20 making a pair therewith is prepared. The sintering material 61 is obtained by mixing minute metallic particles coated with organic matter with an organic solvent. As the metallic particles, silver (Ag) or copper (Cu) having a particle diameter equal to or more than several micrometers but equal to or less than several dozens of micrometers is used, for example. The sintered body 60 can be obtained by heating the sintering material 61 while the sintering material 61 is pressurized. The sintering material 61 has a paste shape or a sheet shape. In a case where the insulating sheet 40 prepared in the procedure of the manufacturing method is an insulating sheet containing glass fiber and a thermosetting resin material immersed in the glass fiber, the resin material may be in a semi-cured state (D stage, B stage). Further, in a case where the insulating sheet 40 prepared in the procedure of the manufacturing method is an insulating sheet including a resin plate and adhesive layers provided on both sides of the resin plate, the resin plate may be in a cured state, and the adhesive layers may be in a semi-cured state (B stage).

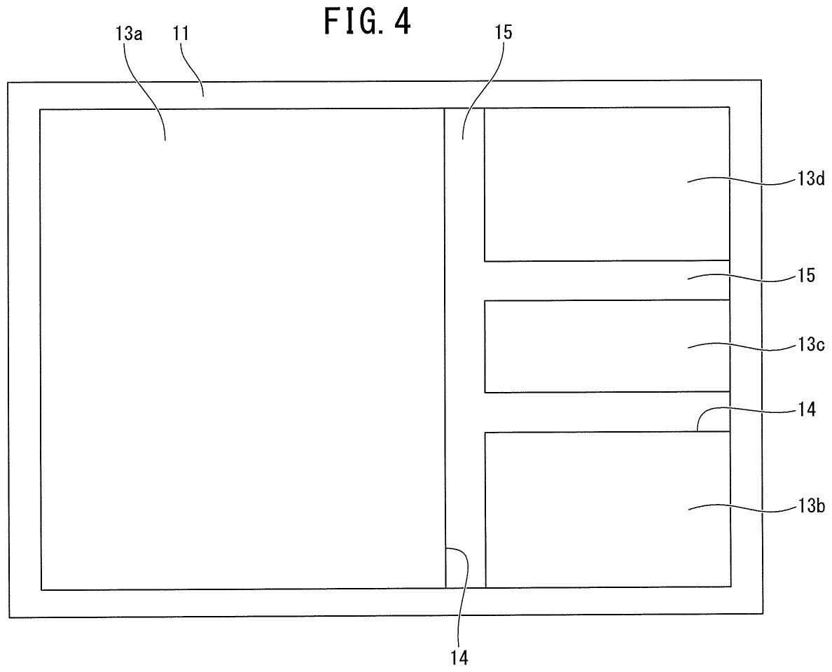

First, the insulating wiring substrate 10 illustrated in FIG. 3 is prepared. The insulating wiring substrate 10 includes the recessed portion 14 constituted by lateral faces of the conductors 13 (for example, the first conductor and the second conductor) and the upper surface 11a of the substrate 11. The insulating material 15 is filled into the recessed portion 14, as illustrated in FIG. 4. In a case where epoxy resin or the like is filled as the insulating material 15, the epoxy resin or the like is hardened before the procedure advances to a subsequent step. In a case where epoxy resin (prepreg) or the like is filled as the insulating material 15, the procedure advances to a subsequent step without hardening the epoxy resin (prepreg) or the like.

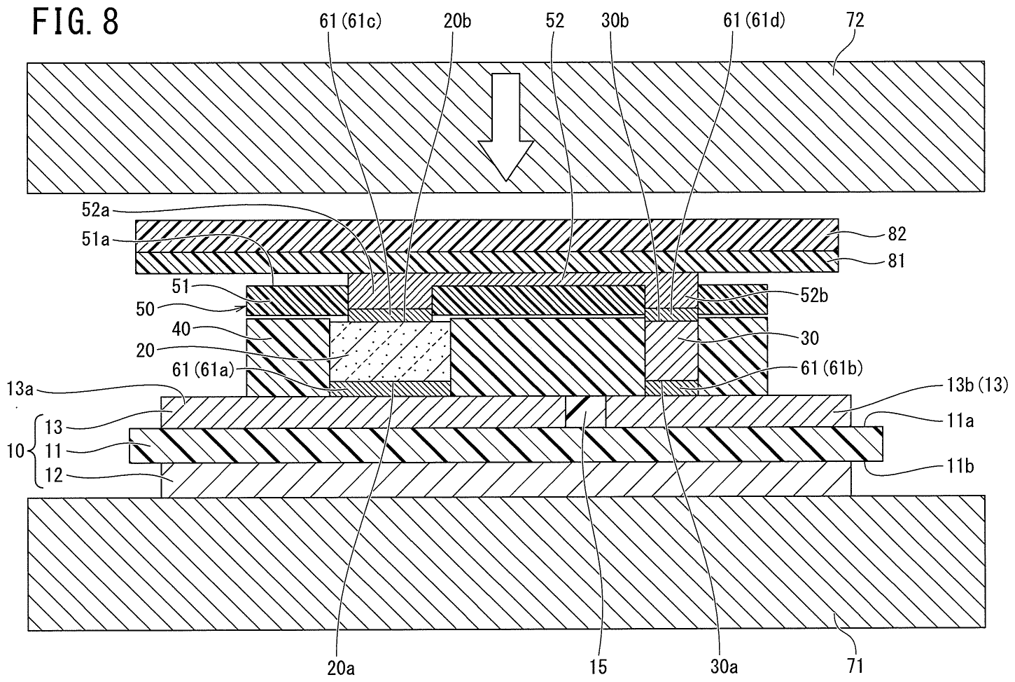

Subsequently, as illustrated in FIG. 5, the semiconductor chip 20 and the conductor block 30 are disposed on the conductors 13. More specifically, as illustrated in FIG. 8, the first surface 20a of the semiconductor chip 20 is disposed on the conductor 13a via a sintering material 61, and the third surface 30a of the conductor block 30 is disposed on the conductor 13b, 13c, 13d via a sintering material 61. The sintering material between the semiconductor chip 20 and the conductor 13a is referred to as a sintering material 61a to distinguish it from the other sintering materials, and the sintering material between the conductor block 30 and the conductor 13b, 13c, 13d is referred to as a sintering material 61b to distinguish it from the other sintering materials. The sintering material 61a corresponds to a first sintering material, and the sintering material 61b corresponds to a third sintering material. When the sintering material 61a and the sintering material 61b are not distinguished from the other sintering materials, they are just referred to as the sintering material 61. Further, each of the conductors 13b, 13c, 13d corresponds to the second conductor. In the present embodiment, as an example, one conductor block 30 is disposed on each of the conductors 13b, 13c, 13d. The sintering material 61a is provided on the first surface 20a of the semiconductor chip 20 or the upper surface of the conductor 13a before the semiconductor chip 20 is disposed on the conductor 13. Similarly, the sintering material 61b is provided on the third surface 30a of the conductor block 30 or the conductor 13b, 13c, 13d before the conductor block 30 is disposed on the conductor 13b, 13c, 13d.

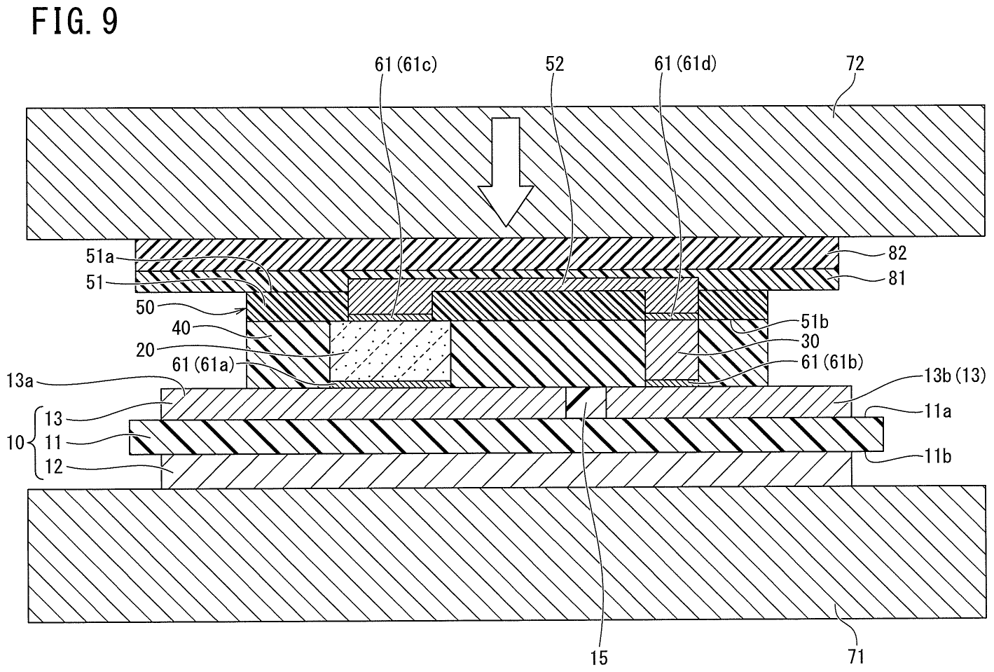

Subsequently, as illustrated in FIG. 6, the insulating sheet 40 is disposed on the insulating wiring substrate 10 to surround the semiconductor chip 20 and the conductor block 30 in a plan view. The insulating sheet 40 is disposed such that the semiconductor chip 20 is exposed from the first opening 41 and the conductor block 30 is exposed from the second opening 42 when the insulating sheet 40 is disposed on the insulating wiring substrate 10. Further, as illustrated in FIGS. 6, 8, the insulating sheet 40 is disposed over the insulating material 15, the conductor 13a, and the conductors 13b, 13c, 13d. The sintering material 61a and the sintering material 61b may have the same thickness. Further, the thickness of the insulating sheet 40 before pressurization and heating are set to be larger than a total thickness of the semiconductor chip 20 and the sintering material 61a and a total thickness of the conductor block 30 and the sintering material 61b. However, the insulating sheet 40 should be provided to have a thickness that can be compressed to a total thickness of the semiconductor chip 20 and the sintered body 60a (or the sintered body 60b) after the insulating sheet 40 is pressurized in steps illustrated in FIGS. 8, 9 (described later).

Subsequently, as illustrated in FIG. 7, the printed wiring board 50 is disposed on the upper surface (a surface opposite to the insulating wiring substrate 10 side) of the insulating sheet 40. More specifically, the insulating substrate 51 is disposed such that the insulating substrate 51 faces the insulating sheet 40. Further, as illustrated in FIG. 8, the insulating substrate 51 is disposed such that the first portion 52a of the lead frame 52 makes contact with the second surface 20b of the semiconductor chip 20 via a sintering material 61, and the second portion 52b makes contact with the fourth surface 30b of the conductor block 30 via a sintering material 61. The sintering material between the first portion 52a and the semiconductor chip 20 is referred to as a sintering material 61c to distinguish it from the other sintering materials, and the sintering material between the second portion 52b and the conductor block 30 is referred to as a sintering material 61d to distinguish it from the other sintering materials. The sintering material 61c corresponds to a second sintering material, and the sintering material 61d corresponds to a fourth sintering material. When the sintering material 61c and the sintering material 61d are not distinguished from the other sintering materials, they are just referred to as the sintering material 61. Before the printed wiring board 50 is disposed on the insulating sheet 40, the sintering material 61c is provided on the second surface 20b of the semiconductor chip 20 or the first portion 52a, and the sintering material 61d is provided on the fourth surface 30b of the conductor block 30 or the second portion 52b. The sintering material 61c and the sintering material 61d may have the same thickness. Note that, when the sintering material 61c and the sintering material 61d are not distinguished from the other sintering materials, they are just referred to as the sintering material 61.

As illustrated in FIG. 10, the lead frame 52 includes the connecting portion 52c connecting the first portion 52a to the second portion 52b. An upper surface (a surface opposite to the insulating substrate 51 side) of the connecting portion 52c is at a position within around ±15 μm from the upper surface 51a of the insulating substrate in the thickness direction. Further, respective end surfaces, of the first portion 52a and the second portion 52b, close to the lower surface 51b are at a position recessed by ⅕ or more but ¼ or less of the thickness of the sintering material 61c or the sintering material 61d before pressurization, from the lower surface 51b of the insulating substrate 51.

Subsequently, as illustrated in FIGS. 8, 9, constituents from the insulating wiring substrate 10 to the printed wiring board 50 thus stacked as described above are heated while the constituents are pressurized. More specifically, in a state where the constituents from the insulating wiring substrate 10 to the printed wiring board 50 are stacked, the constituents are heated while the constituents are pressurized between a lower metal die 71 and an upper metal die 72. The lower metal die 71 and the upper metal die 72 are made of a metal material for metal die or a ceramic material (e.g., silicon nitride or the like), for example. The lower metal die 71 and the upper metal die 72 are heated in advance to a recommended temperature for sintering the sintering material 61, e.g., a temperature of around 250° C. or more. Further, an application pressure is a recommended pressure for sintering the sintering material 61, e.g., around 10 MPa. The constituents from the insulating wiring substrate 10 to the printed wiring board 50 are disposed at a time or components thereof are disposed sequentially as described above on the lower metal die 71. Then, the constituents from the insulating wiring substrate 10 to the printed wiring board 50 are heated while the constituents are pressurized between the lower metal die 71 and the upper metal die 72. More specifically, a protective sheet 81 and a buffer material 82 are disposed on the upper surface of the printed wiring board 50 in this order, and the constituents from the insulating wiring substrate 10 to the buffer material 82 are heated while the constituents are pressurized between the lower metal die 71 and the upper metal die 72. The protective sheet 81 is made of, for example, fluoric resin (e.g., polytetrafluoroethylene (PTFE)) and has, for example, a thickness of 0.1 mm or more but 0.5 mm or less. It is desirable that the buffer material 82 be made of a material having a low elastic modulus even during sintering of the sintering material 61, and the buffer material 82 is constituted by a carbon sheet, for example. The buffer material 82 can absorb recesses and projections on the upper surface of the printed wiring board 50. The buffer material 82 can absorb recesses and projections of around ±15 μm in the thickness direction, for example. On this account, the buffer material 82 can absorb a step between the upper surface 51a of the insulating substrate 51 and the upper surface of the lead frame 52 at the time of pressurization.

By heating the constituents from the insulating wiring substrate 10 to the printed wiring board 50 while the constituents are pressurized, the main part 1A illustrated in FIG. 1 is obtained. More specifically, by heating while pressurizing, the sintered body 60 obtained by hardening metallic fine particles of the sintering material 61 by heating, and the insulating sheet 40 thermally cured are obtained. More specifically, as the sintered body 60, the sintered bodies 60a, 60b, 60c, 60d can be obtained by one pressurization and heating. The sintered body 60 has a thickness of around ⅕ or more but ¼ or less of the thickness of the sintering material 61. Accordingly, after pressurization and heating, the sintered bodies 60c, 60d become thin to such an extent that the sintered bodies 60c, 60d are fitted in the first via-hole V1 and the second via-hole V2, so that the insulating substrate 51 makes contact with the insulating sheet 40. Further, the insulating sheet 40 becomes thin by pressurization, so that the thickness of the insulating sheet 40 becomes generally equal to the total thickness of the semiconductor chip 20 and the sintering material 61a and the total thickness of the conductor block 30 and the sintering material 61b. Further, the thermosetting resin material seeps out of the glass fiber in the insulating sheet 40 due to pressurization to fill a gap between the insulating sheet 40 and each of the semiconductor chip 20 and the conductor block 30, and even if the gap remains, the gap is slight. Thus, the main part 1A in which components are joined to each other by the sintered bodies 60 is obtained. Then, necessary steps other than the steps described above are performed to join the main part 1A to the copper base 1B and seal the main part 1A by the sealing resin 1C, and hereby, the semiconductor module 1 is almost completed.

<<Main Effects of Semiconductor Module and Manufacturing Method thereof>>

The following describes main effects of the semiconductor module 1 and the manufacturing method thereof, but before that, an overview will be described first. Conventionally, a lower surface of a semiconductor chip provided in a semiconductor module is joined to an insulating wiring substrate by use of a solder material such as tin antimony (SnSb) solder, tin silver (SnAg) solder, or the like, for example. Further, conventionally, wires are bonded to an upper surface of the semiconductor chip. However, since conducting current increases due to the use of a SiC semiconductor chip, a wiring method for joining, by solder, a lead frame that can have a low resistance is used. Since the semiconductor module is a circuit dealing with heavy current, heat is locally generated due to a high resistance or low heat transfer in wired connection (Joule heat Q=I2Rt, current I, resistance R, time t). On this account, it is important as an electric circuit to restrain heat generation (internal loss) if possible.

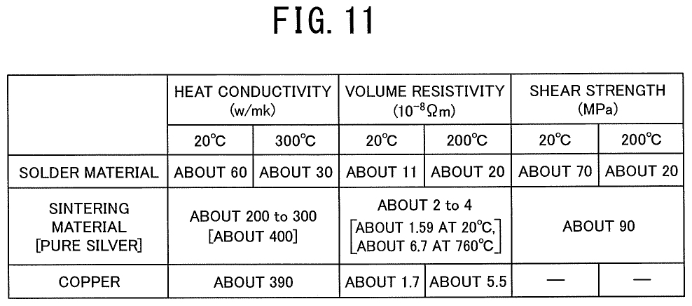

With reference to FIG. 11, characteristics of various materials such as a solder material and a sintered body will be described. The sintered body has a melting point higher than that of the solder material. The sintered body has a heat conductivity that is 10 times larger than that of the solder material, and even when the temperature of the sintered body is increased to 300° C., the heat conductivity of the sintered body does not greatly deteriorate. Further, the sintered body has a volume resistivity that is 10 times lower than that of the solder material, and even when the temperature of the sintered body is increased to 200° C., the volume resistivity of the sintered body does not greatly deteriorate. On this account, when the semiconductor chip 20 is mounted by use of the sintered body, it is possible to restrain an electric loss in an electric circuit and to restrain heat generation in compared with a case where the solder material is used. By joining the semiconductor chip 20 to the insulating wiring substrate 10 by use of the sintered body, it is possible to enhance a heat dissipation effect to the copper base 1B in comparison with a case where the solder material is used. Note that, as illustrated in FIG. 11, silver and copper are also similar to the sintered body.

Further, the following describes shear strengths in cases of using the solder material and the sintered body to connect the semiconductor chip to a copper material. The shear strength in the case of using the sintered body is higher than that in the case of the solder material, and even when the temperature of the sintered body is increased to 200° C., the shear strength of the sintered body does not greatly deteriorate. Further, it is thought that the shear strength of the sintered body is higher than the strength of a joined portion of a wire. The reliability of the semiconductor module can be raised by use of the sintered body.

Since the sintered body has the characteristics described above, it is expected to apply the sintered body to a semiconductor module including a semiconductor chip having a high temperature during operation. However, in order to obtain the sintered body, it is necessary to heat a sintering material while the sintering material is pressurized uniformly. Further, when a lead frame is pressurized, a part extending along a horizontal direction might bend. When a part without a member serving as a support under the part is pressurized, the part might be curved or damaged.

In the meantime, in the semiconductor module 1 and the manufacturing method thereof according to the first embodiment of this disclosure, the insulating sheet 40 is disposed on the insulating wiring substrate 10 to surround the semiconductor chip 20 in a plan view. Then, in a state where the printed wiring board including the lead frame 52 provided on the flat-shaped insulating substrate 51 is disposed to face the insulating sheet 40, the constituents from the insulating wiring substrate 10 to the printed wiring board 50 are heated while the constituents are pressurized. Since the insulating sheet 40 supports the printed wiring board 50 in contact with the printed wiring board 50, it is possible to restrain the printed wiring board 50 from being greatly curved or damaged and to restrain the lead frame 52 from greatly bending. Further, since a pressure is applied via the flat-shaped printed wiring board 50, it is possible to restrain a large unevenness between the pressure applied to the sintering material 61 provided between the semiconductor chip 20 and the insulating wiring substrate 10 and the pressure applied to the sintering material 61 provided between the conductor block 30 and the insulating wiring substrate 10, thereby making it possible to apply the pressure as equally as possible. Accordingly, even in a case where a plurality of sintering materials 61 is disposed along the thickness direction, it is possible to restrain a pressure unevenness in the sintering material in a lower layer. Further, it is possible to form a plurality of sintered bodies along the thickness direction by one pressurization and heating step, thereby making it possible to restrain an increase in manufacturing steps and to restrain a manufacturing cost. Further, since the sintered body and the lead frame 52 are used instead of a solder material and a wire to join the semiconductor chip 20 to a wiring line, it is possible to achieve the semiconductor module 1 having a high heat-resisting property. More specifically, it is possible to achieve the semiconductor module 1 having a high heat-resisting property of around 175° C. or more but 200° C. or less. Hereby, it is possible to improve the reliability and the durability of the semiconductor module 1. Further, since the sintered body 60 having a high heat conductivity is used, it is possible to enhance a heat dissipation effect of the semiconductor module 1. The sintered body 60 having a high heat conductivity is used, and therefore, even in a case where the area of the semiconductor chip 20 is reduced, it is possible to restrain the heat dissipation effect from decreasing. This makes it possible to enhance the heat dissipation effect of the semiconductor module 1.

Further, in the semiconductor module 1 and the manufacturing method thereof according to the first embodiment of this disclosure, the second portion 52b of the lead frame 52 is electrically connected to the insulating wiring substrate 10 via the conductor block 30 and the sintering material 61. By use of the conductor block 30 having the same thickness as the semiconductor chip 20, the first portion 52a and the second portion 52b can have the same dimension along the thickness direction, and the sintering material 61 can be easily disposed on the lead frame 52. Further, even in a case where the thickness of the semiconductor chip 20 changes, when another conductor block 30 having the same thickness as the semiconductor chip is used, it is not necessary to adjust the lengths of the first portion 52a and the second portion 52b, and the same lead frame 52 can be used.

Further, the semiconductor module 1 and the manufacturing method thereof according to the first embodiment of this disclosure include a step of filling the insulating material 15 into the recessed portion 14 constituted by the lateral faces of the conductor 13a and the conductor 13b, 13c, 13d and the upper surface 11a of the substrate 11. By filling the insulating material 15 into the recessed portion 14, it is possible to fill a step between the upper surface of the conductor 13 and the upper surface 11a of the substrate 11. Hereby, it is possible to restrain a part, of the printed wiring board 50, that overlaps with the recessed portion 14 in a plan view, more specifically, the connecting portion 52c of the lead frame 52 from bending at the time of pressurization. Hereby, it is possible to improve the reliability of the semiconductor module 1.

Further, in the semiconductor module 1 and the manufacturing method thereof according to the first embodiment of this disclosure, respective end surfaces of the first portion 52a and the second portion 52b are at a position recessed from the lower surface 51b of the insulating substrate 51 by ⅕ or more but ¼ or less of the thickness of the sintering material 61c before pressurization in the thickness direction. In the pressurization and heating step, the sintering materials 61 become thin to such an extent that the sintering materials 61 are fitted in the first via-hole V1 and the second via-hole V2, and the sintering materials 61a, 61b are pressurized by the printed wiring board 50. Accordingly, it is possible to restrain the pressures applied to the sintering materials 61a, 61b from being largely uneven, thereby making it possible to apply the pressure as equally as possible. Accordingly, even in a case where a plurality of sintering materials 61 is disposed along the thickness direction, it is possible to restrain a pressure unevenness in the sintering material on a lower layer. Hereby, it is possible to improve the reliability of the semiconductor module 1.

Further, the semiconductor module 1 according to the first embodiment of this disclosure includes the insulating sheet 40 provided on the insulating wiring substrate 10 to surround the semiconductor chip 20 in a plan view. Since the insulating sheet 40 fills a space between the insulating wiring substrate 10 and the printed wiring board 50, it is possible to restrain the main part 1A from warping during operation. Hereby, it is possible to improve the reliability of the semiconductor module 1.

Further, in the semiconductor module 1 according to the first embodiment of this disclosure, a wiring line on the upper side is drawn by use of the printed wiring board 50 instead of a wire. This makes it possible to decrease a distance between the wiring line on the upper side and the insulating wiring substrate 10 as a wiring line on the lower side. Since the insulating sheet 40 as a dielectric material is provided therebetween, it is possible to couple the printed wiring board 50 with the insulating wiring substrate 10 in an electrostatic capacitive manner, thereby making it possible to downsize inductance of the wiring line.

### Second Embodiment

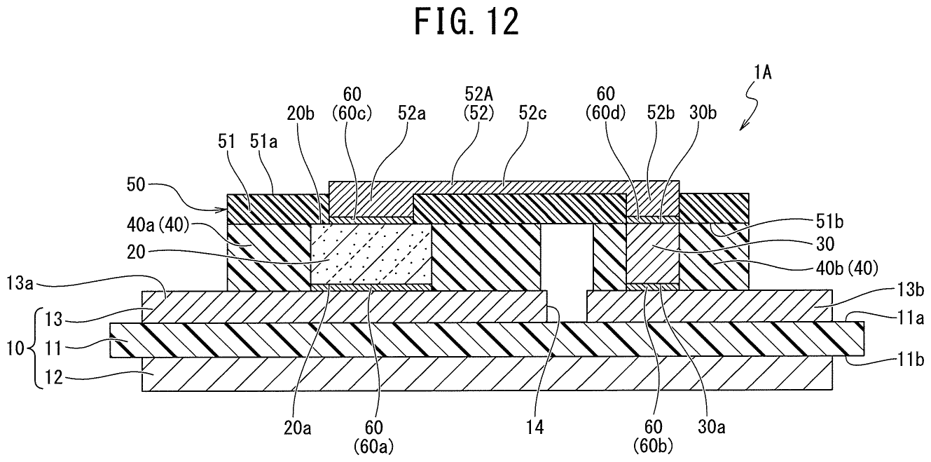

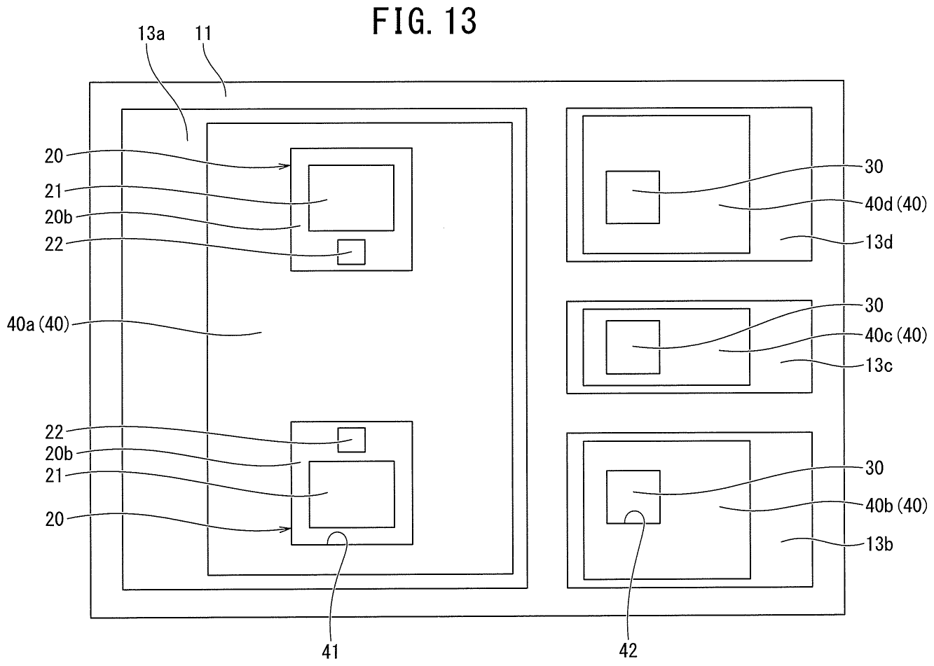

The following describes a second embodiment of this disclosure illustrated in FIG. 12. The main part 1A of the semiconductor module 1 according to the second embodiment is different from the main part 1A of the semiconductor module 1 according to the first embodiment mainly in that: the recessed portion 14 is not filled with the insulating material 15; and the insulating sheet 40 is not disposed at the position overlapping with the recessed portion 14 but is disposed separately on a part above the conductor 13a surrounding the semiconductor chip 20 and a part above the conductor 13b, 13c, 13d surrounding the conductor block 30. The other configurations of the main part 1A are basically similar to those of the main part 1A described above. The constituent components described above have the same reference signs as in the first embodiment and are not described herein. Further, the procedure drawings of the manufacturing method illustrated in FIG. 13 will be referred to appropriately to describe the positional relationship of the constituent components.

In the present embodiment, as illustrated in FIG. 12, the recessed portion 14 is not filled with the insulating material 15, so that a step is formed between the conductors 13. In the present embodiment, as illustrated in FIG. 13, the insulating sheet 40 is provided in a divided manner on each of the conductors 13 electrically separated from each other such that the insulating sheet 40 avoids a step in the recessed portion 14. For example, the insulating sheet 40 is provided separately on the part above the conductor 13a surrounding the semiconductor chip 20 and the part above the conductor 13b surrounding the conductor block 30.

### <<Manufacturing Method of Semiconductor Module>>

The following describes a manufacturing method of the main part 1A of the semiconductor module 1 with reference to FIGS. 13 to 15. The present embodiment mainly describes points different from the manufacturing method described in the first embodiment, and the drawings described in the first embodiment will be used as necessary for description.

First, among the steps described in the first embodiment, the steps until the step illustrated in FIG. 5 are performed except the step of filling the insulating material 15 into the recessed portion 14 illustrated in FIG. 4. Then, as illustrated in FIG. 13, an insulating sheet 40a is disposed at a position overlapping with the conductor 13a, an insulating sheet 40b is disposed at a position overlapping with the conductor 13b, an insulating sheet 40c is disposed at a position overlapping with the conductor 13c, an insulating sheet 40d is disposed at a position overlapping with the conductor 13d, and after that, the step illustrated in FIG. 7 is performed. Note that, when the insulating sheets 40a, 40b, 40c, 40d are not distinguished from each other, they are just referred to as the insulating sheet 40.

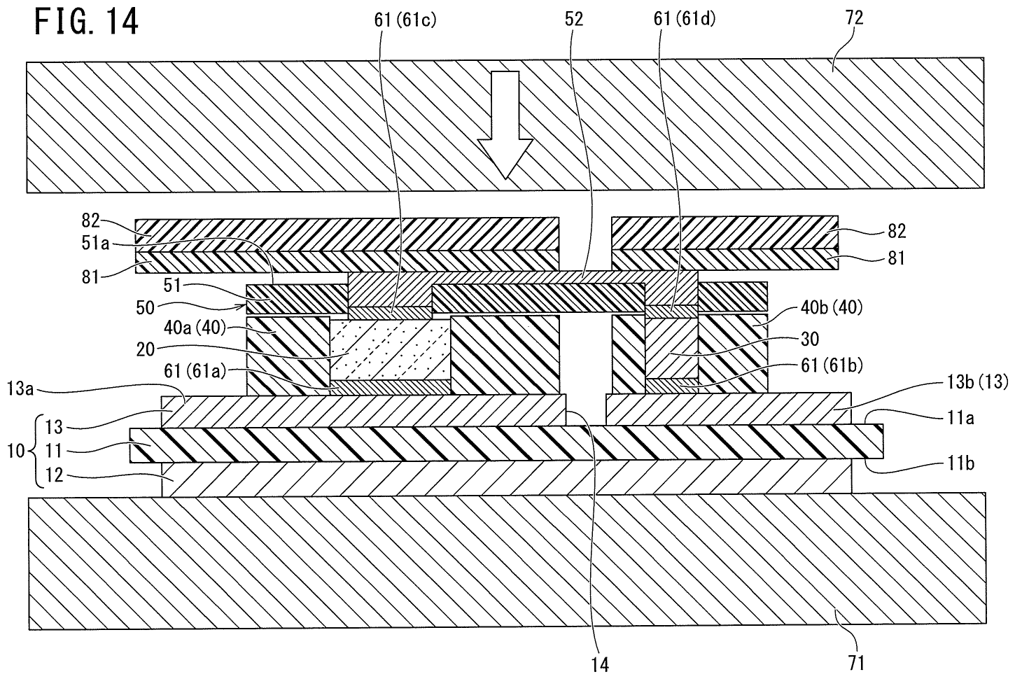

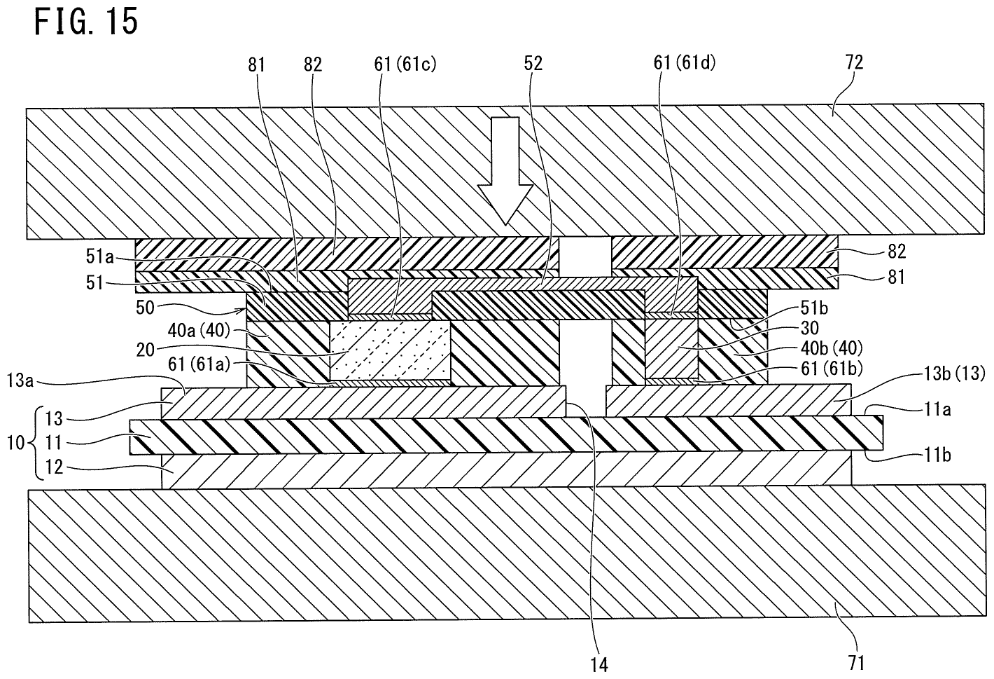

Subsequently, as illustrated in FIGS. 14, 15, the constituents from the insulating wiring substrate 10 to the printed wiring board 50 stacked as described above are heated while the constituents are pressurized between the lower metal die 71 and the upper metal die 72. At this time, at least the buffer material 82 out of the protective sheet 81 and the buffer material 82 is disposed at a position that does not overlap with the recessed portion 14 in a plan view. Hereby, a pressure applied to the step of the recessed portion 14 and the connecting portion 52c of the lead frame 52 that overlaps with the recessed portion 14 in a plan view can be relaxed. Hereby, it is possible to restrain the connecting portion 52c from bending. The subsequent steps are the same as the steps described in the first embodiment and therefore not described herein.

### Third Embodiment

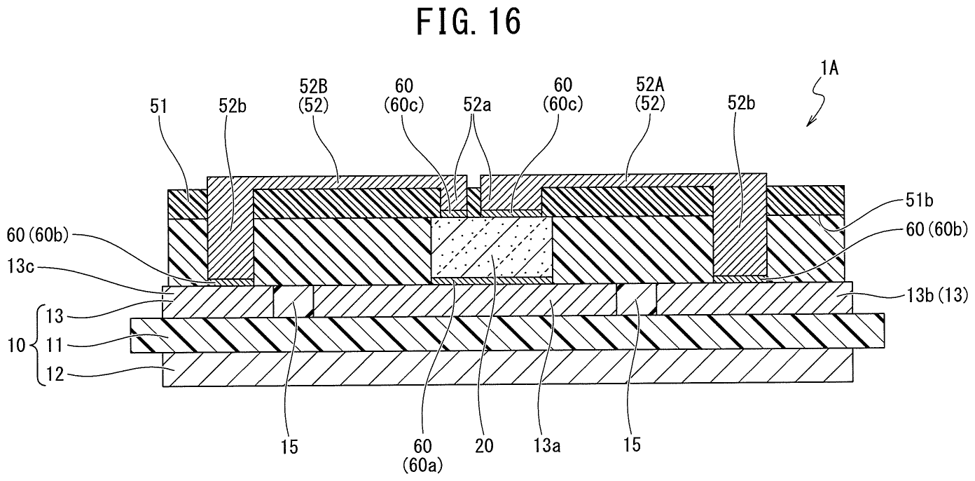

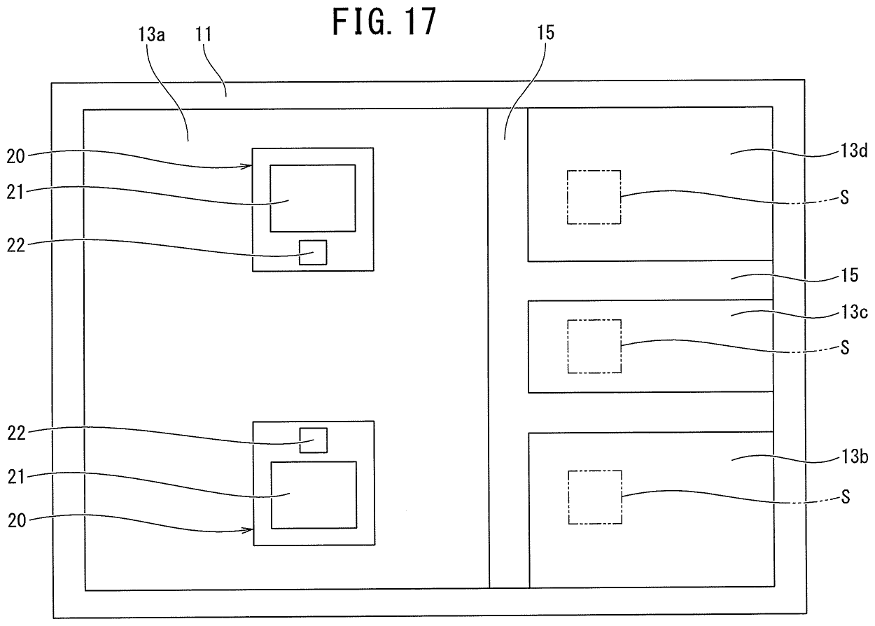

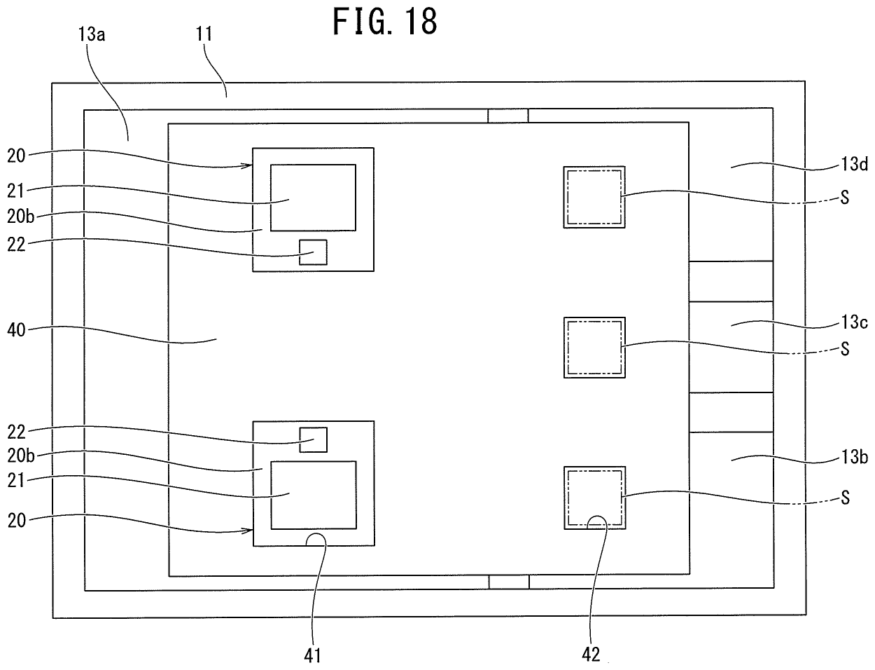

The following describes a third embodiment of this disclosure illustrated in FIG. 16. The main part 1A of the semiconductor module 1 according to the third embodiment is different from the main part 1A of the semiconductor module 1 according to the first embodiment mainly in that no conductor block 30 is provided. The other configurations of the main part 1A are basically similar to those of the main part 1A described in the first embodiment. The constituent components described above have the same reference signs as in the first embodiment and are not described herein. Further, the procedure drawings of the manufacturing method illustrated in FIGS. 17, 18 will be referred to appropriately to describe the positional relationship of the constituent components.

The configuration of the first portion 52a of the lead frame 52 according to the present embodiment is the same as that of the first embodiment, but the configuration of the second portion 52b is different from that of the first embodiment. The second portion 52b is joined to the conductor 13 without the conductor block 30. More specifically, the second portion 52b is directly joined to the conductor 13b or the conductor 13c via the sintered body 60 (for example, the sintered body 60b). The second portion 52b is provided to have a dimension, along the extending direction, that is larger than that of the first portion 52a and projects from the lower surface 51b of the insulating substrate 51. The dimension of the second portion 52b along the extending direction should have a dimension that allows the second portion 52b to be directly connected to the conductor 13 via the sintered body 60.

### <<Manufacturing Method of Semiconductor Module>>

The following describes a manufacturing method of the semiconductor module 1 with reference to FIGS. 17, 18. The present embodiment mainly describes points different from the manufacturing method described in the first embodiment, and the drawings described in the first embodiment will be used as necessary for description. First, the steps illustrated in FIGS. 3, 4 are performed. After that, as illustrated in FIG. 17, the semiconductor chip 20 is disposed on the conductor 13a via the sintering material 61 (not illustrated). However, no conductor block 30 is provided on the conductor 13. A region S as a partial region of the conductor 13b, 13c, 13d as indicated by an alternate long and short dash line is a region to which a lead frame is joined later. Subsequently, as illustrated in FIG. 18, the insulating sheet 40 is disposed on the insulating wiring substrate 10 to surround the semiconductor chip 20 in a plan view. More specifically, the insulating sheet 40 is disposed such that the semiconductor chip 20 is exposed from the first opening 41 and the region S is exposed from the second opening 42 when the insulating sheet 40 is disposed on the insulating wiring substrate 10. After that, as illustrated in FIG. 7, the printed wiring board 50 is disposed on the upper surface of the insulating sheet 40. Note that the second portion 52b can be joined to the region S by providing the sintering material 61 (for example, the sintering material 61b) in the region S or the second portion 52b before the printed wiring board 50 is disposed on the insulating sheet 40. Hereby, the number of necessary components can be reduced. The subsequent steps are the same as the steps described in the first embodiment and therefore not described herein.

### Other Embodiments

The first to third embodiments of this disclosure have been described above, but it should be not understood that the description and the drawings as part of this disclosure restrict this disclosure. Various alternative embodiments, examples, and operational technologies will become clear to a person skilled in the art from this disclosure.

Further, for example, the semiconductor module 1 in FIG. 1 is sealed by the sealing resin 1C in a state where the main part 1A is joined to the copper base 1B. However, the main part 1A may not be joined to the copper base 1B, and only the main part 1A may be sealed by the sealing resin 1C.

Further, for example, even the semiconductor modules 1 according to the second and third embodiments can yield effects similar to those of the semiconductor module 1 according to the first embodiment.

Further, the configurations disclosed in the first to third embodiments can be combined appropriately as far as no consistency occurs. Thus, it is needless to say that this disclosure includes various embodiments and so on that are not described herein. Accordingly, the technical scope of this disclosure is determined only by the invention specification matter according to proper claims from the above description.

1. A semiconductor module manufacturing method comprising:
preparing an insulating wiring substrate including a substrate and a first conductor provided on an upper surface of the substrate, a semiconductor chip having a first surface and a second surface, and a printed wiring board including an insulating substrate and a lead frame provided on the insulating substrate, the lead frame including a first portion provided in a first via-hole penetrating through the insulating substrate;
disposing the first surface of the semiconductor chip on the first conductor via a first sintering material;
disposing an insulating sheet on the insulating wiring substrate to surround the semiconductor chip in a plan view;
disposing the printed wiring board such that the insulating substrate faces the insulating sheet, and the first portion makes contact with the second surface via a second sintering material; and
performing heating while pressurization is performed between an upper metal die and a lower metal die in a state where the insulating wiring substrate, the semiconductor chip, the insulating sheet, and the printed wiring board are disposed and stacked.

2. The semiconductor module manufacturing method according to claim 1, wherein:
the insulating wiring substrate includes a second conductor provided on the upper surface of the substrate and electrically isolated from the first conductor;
the lead frame includes a second portion provided in a second via-hole penetrating through the insulating substrate at a position different from the first via-hole;
the semiconductor module manufacturing method further includes
preparing a conductor block having a third surface and a fourth surface, and
disposing the third surface of the conductor block on the second conductor via a third sintering material;
the disposing the insulating sheet includes disposing the insulating sheet to surround the conductor block in a plan view; and
the disposing the printed wiring board includes disposing the printed wiring board such that the second portion makes contact with the fourth surface via a fourth sintering material.

3. The semiconductor module manufacturing method according to claim 2, wherein the conductor block has the same thickness as the semiconductor chip.

4. The semiconductor module manufacturing method according to claim 2, further comprising:
filling an insulating material into a recessed portion constituted by lateral faces of the first conductor and the second conductor and the upper surface of the substrate, wherein the insulating sheet is disposed over the insulating material, the first conductor, and the second conductor to surround the semiconductor chip and the conductor block in a plan view.

5. The semiconductor module manufacturing method according to claim 2, wherein the insulating sheet is provided separately for a part surrounding the semiconductor chip above the first conductor and for a part surrounding the conductor block above the second conductor without being disposed at a position overlapping with the recessed portion constituted by the lateral faces of the first conductor and the second conductor and the upper surface of the substrate in a plan view.

6. The semiconductor module manufacturing method according to claim 1, wherein the insulating sheet contains glass fiber and a thermosetting resin material.

7. The semiconductor module manufacturing method according to claim 6, wherein the thermosetting resin material is any of polyimide, polyamideimide, and epoxy based resin.

8. The semiconductor module manufacturing method according to claim 1, wherein the insulating sheet includes a resin plate and adhesive layers provided on both surfaces of the resin plate.

9. The semiconductor module manufacturing method according to claim 8, wherein:
the resin plate is any of polyimide, polyamideimide, liquid crystalline polymer, polyphenylene sulfide, and polyether ketone; and
the adhesive layers are epoxy resin.

10. The semiconductor module manufacturing method according to claim 1, wherein the insulating sheet is prepreg.

11. The semiconductor module manufacturing method according to claim 1, wherein the insulating sheet has a heat-resisting property at 150° C. or more.

12. The semiconductor module manufacturing method according to claim 1, wherein:
the insulating sheet surrounding the semiconductor chip in a plan view has a first opening; and
the semiconductor chip is exposed from the first opening when the insulating sheet is disposed on the insulating wiring substrate.

13. The semiconductor module manufacturing method according to claim 2, wherein:
the insulating sheet surrounding the conductor block in a plan view has a second opening; and
the conductor block is exposed from the second opening when the insulating sheet is disposed on the insulating wiring substrate.

14. The semiconductor module manufacturing method according to claim 2, wherein the lead frame includes a connecting portion connecting the first portion to the second portion, the connecting portion having an upper surface at a position within ±15 μm in a thickness direction from an upper surface of the insulating substrate.

15. The semiconductor module manufacturing method according to claim 2, wherein the heating is performed in a state where a protective sheet and a buffer material are disposed between the upper metal die and the printed wiring board.

16. The semiconductor module manufacturing method according to claim 2, wherein the first portion and the second portion have respective end surfaces at a position recessed from a lower surface of the insulating substrate by ⅕ or more but ¼ or less of a thickness of the second sintering material before pressurization in the thickness direction.

17. The semiconductor module manufacturing method according to claim 1, wherein:
the insulating wiring substrate includes a second conductor provided on the upper surface of the substrate and electrically isolated from the first conductor;
the lead frame includes a second portion provided in a second via-hole penetrating through the insulating substrate at a position different from the first via-hole;
the disposing the insulating sheet includes disposing the insulating sheet on the second conductor such that a partial region of the second conductor is exposed; and
the disposing the printed wiring board includes disposing the printed wiring board such that the second portion makes contact with the second conductor via a third sintering material.

18. The semiconductor module manufacturing method according to claim 14, wherein the heating is performed in a state where a protective sheet and a buffer material are disposed between the upper metal die and the printed wiring board.

19. A semiconductor module comprising:
an insulating wiring substrate including a substrate and a first conductor provided on an upper surface of the substrate;
a semiconductor chip having a first surface and a second surface, the first surface being joined to the first conductor via a first sintered body;
an insulating sheet provided on the insulating wiring substrate to surround the semiconductor chip in a plan view; and
a printed wiring board including an insulating substrate and a lead frame provided on the insulating substrate, the lead frame including a first portion provided in a first via-hole penetrating through the insulating substrate and the first portion being joined to the second surface via a second sintered body, the insulating substrate facing the insulating sheet.
